(19) United States
(12) Patent Application Publication
(10) Pub. No.: US 2016/0204139 A1
(43) Pub. Date: Jul. 14, 2016

(54) THIN FILM TRANSISTOR SUBSTRATE AND METHOD FOR MANUFACTURING SAME

(71) Applicant: JOLED INC., Chiyoda-ku, Tokyo (JP)

(72) Inventors: Yuji KISHIDA, Tokyo (JP); Takahiro KAWASHIMA, Osaka (JP); Yoshiaki NAKAZAKI, Tokyo (JP)

(73) Assignee: JOLED INC., Tokyo (JP)

(21) Appl. No.: 14/917,076

(22) PCT Filed: May 27, 2014
(86) PCT No.: PCT/JP2014/002789

§ 371 Date: Mar. 7, 2016

(30) Foreign Application Priority Data
Sep. 30, 2013 (JP) 2013-205684

(51) Int. Cl. H01L 27/12; H01L 29/786

(52) U.S. Cl. CPC H01L 27/1255; H01L 27/1248; H01L 29/78693

(57) ABSTRACT

A thin film transistor substrate includes: a gate electrode and a first electrode of a capacitor formed above a substrate so as to be arranged along a plane of the substrate; a gate insulating film formed on the gate electrode; a semiconductor layer formed on the gate insulating film; an insulating layer formed on the semiconductor layer and above the first electrode so as to expose portions of the semiconductor layer; a source electrode and a drain electrode formed above the insulating layer so as to be connected to the semiconductor layer at the exposed portions of the semiconductor layer; and a second electrode of the capacitor formed above the insulating layer, at a position opposite the first electrode, and the insulating layer above the gate electrode is thicker than the insulating layer above the first electrode.

### TECHNICAL FIELD

The present disclosure relates to a thin film transistor substrate and a method for manufacturing the same.

### BACKGROUND ART

Thin-film transistors (TFTs) are widely used as switching elements or drive elements in active-matrix display devices such as liquid-crystal display devices or organic electro-luminescence (EL) display devices.

Conventionally, a technique for continuously forming a gate insulating film, a semiconductor layer, and a channel protective layer without exposure to the air during manufacture of a thin film transistor is known (Patent Literature (PTL) 1). This reduces process damage to the semiconductor layer, making it possible to manufacture a thin film transistor having stable properties.

### CITATION LIST

### Patent Literature

[PTL 1] Japanese Unexamined Patent Application Publication No, 2010-056546

### SUMMARY OF INVENTION

### Technical Problem

With the above-described conventional technique, however, it is not possible to manufacture a thin film transistor having sufficiently stable properties.

The thin film transistor in PTL 1 has a side-contact structure. The semiconductor layer is partially scraped off through etching when forming a contact region between the semiconductor layer and each of source and drain electrodes. This leads, for example, to variations in threshold voltage in initial properties.

When the thin film transistor is used in a display device, the thin film transistor is provided on the same substrate on which a capacitor and other elements are provided. In this case, the sizes of the thin film transistor and the capacitor to be provided on the substrate are limited, which means that it is difficult to give the capacitor a large capacitance.

In view of this, the present disclosure provides a reliable thin film transistor substrate which has more stable properties and allows a capacitor to have a large capacitance, and also provides a method for manufacturing the same.

### Solution to Problem

In order to solve the aforementioned problem, a thin film transistor substrate according to an aspect of the present disclosure includes: a substrate; a gate electrode and a first electrode of a capacitor formed above the substrate, the gate electrode and the first electrode being arranged along a plane of the substrate; a gate insulating film formed on the gate electrode; a semiconductor layer formed on the gate insulating film; an insulating layer formed on the semiconductor layer and above the first electrode, the insulating layer leaving portions of the semiconductor layer exposed; a source electrode and a drain electrode formed above the insulating layer, the source electrode and the drain electrode being connected to the semiconductor layer at the exposed portions of the semiconductor layer; and a second electrode of the capacitor formed above the insulating layer, at a position opposite the first electrode, wherein the insulating layer above the gate electrode is thicker than the insulating layer above the first electrode.

Furthermore, a method for manufacturing a thin film transistor substrate according to an aspect of the present disclosure includes: (i) forming a gate electrode and a first electrode of a capacitor above a substrate, the gate electrode and the first electrode being arranged along a plane of the substrate; (ii) forming a gate insulating film, a semiconductor layer, and an insulating layer in sequence by continuously stacking a first insulating film, a semiconductor film, and a second insulating film in sequence, on the gate electrode and the first electrode; and (iii) exposing portions of the semiconductor layer, forming a source electrode and a drain electrode above the insulating layer, and forming a second electrode of the capacitor above the first electrode and the insulating layer, the source electrode and the drain electrode being connected to the semiconductor layer at the exposed portions, wherein in step (ii), at least a portion of the second insulating film above the first electrode is removed to make the insulating layer above the gate electrode thicker than the insulating layer above the first electrode.

### Advantageous Effects of Invention

According to the present disclosure, it is possible to provide a reliable thin film transistor substrate which has more stable properties and allows a capacitor to have a large capacitance, and also provide a method for manufacturing the same.

### BRIEF DESCRIPTION OF DRAWINGS

FIG. 1 is a cut-out perspective view of an organic EL display device according to an embodiment.

FIG. 2 is a plan view illustrating the configuration of a pixel in an organic EL display device according to an embodiment.

FIG. 3 is a circuit diagram schematically illustrating the configuration of a pixel circuit in an organic EL display device according to an embodiment.

FIG. 4 is a schematic diagram of a cross section of a thin film transistor substrate according to an embodiment.

FIG. 5 is a schematic diagram of a cross section of a thin film transistor substrate according to an embodiment illustrating a manufacturing method.

FIG. 6 is a schematic diagram of a cross section of a thin film transistor according to a comparative example.

FIG. 7 is a schematic diagram of a cross section of a thin film transistor according to a comparative example illustrating a manufacturing method.

FIG. 8A illustrates the relationship between gate voltage and each of current and mobility measured in a PBTS test for a thin film transistor according to a comparative example.

FIG. 8B illustrates the relationship between gate voltage and each of current and mobility measured in a PBTS test for a thin film transistor according to an embodiment.

FIG. 9A illustrates changes in threshold voltage measured in a PBTS test for thin film transistors according to an embodiment and a comparative example.

FIG. 9B illustrates changes in S value measured in a PBTS test for thin film transistors according to an embodiment and a comparative example.

FIG. 9C illustrates changes in mobility measured in a PBTS test for thin film transistors according to an embodiment and a comparative example.

FIG. 10A illustrates the relationship between gate voltage and each of current and mobility measured in an NBTS test for a thin film transistor according to a comparative example.

FIG. 10B illustrates the relationship between gate voltage and each of current and mobility measured in an NBTS test for a thin film transistor according to an embodiment.

FIG. 11A illustrates changes in threshold voltage measured in an NBTS test for thin film transistors according to an embodiment and a comparative example.

FIG. 11B illustrates changes in S value measured in an NBTS test for thin film transistors according to an embodiment and a comparative example.

FIG. 11C illustrates changes in mobility measured in an NBTS test for thin film transistors according to an embodiment and a comparative example.

### DESCRIPTION OF EMBODIMENTS

### Outline of Present Disclosure

A thin film transistor substrate according to the present disclosure includes: a substrate; a gate electrode and a first electrode of a capacitor formed above the substrate, the gate electrode and the first electrode being arranged along a plane of the substrate; a gate insulating film formed on the gate electrode; a semiconductor layer formed on the gate insulating film; an insulating layer formed on the semiconductor layer and above the first electrode, the insulating layer leaving portions of the semiconductor layer exposed; a source electrode and a drain electrode formed above the insulating layer, the source electrode and the drain electrode being connected to the semiconductor layer at the exposed portions of the semiconductor layer; and a second electrode of the capacitor formed above the insulating layer, at a position opposite the first electrode, wherein the insulating layer above the gate electrode is thicker than the insulating layer above the first electrode.

With this, the insulating layer between the first electrode and the second electrode of the capacitor is thinner than the insulating film above the gate electrode, resulting in the capacitor having a large capacitance. The thin film transistor substrate has a channel protective (top-contact) transistor having the source electrode and the drain electrode above the insulating layer. Since a channel protective film on the semiconductor layer is thick, the thin film transistor has improved reliability with more stable properties. Thus, the thin film transistor substrate according to the present disclosure has improved reliability with more stable properties and allows a capacitor to have a large capacitance.

Furthermore, in the thin film transistor substrate according to the present disclosure, the insulating layer above the gate electrode may include: a first layer; and a second layer formed on the first layer, and the insulating layer above the first electrode may include only the second layer among the first layer and the second layer.

With this, the insulating layer above the gate electrode includes the first layer and the second layer, whereas the insulating layer between the electrodes of the capacitor does not include the first layer but includes the second layer. Therefore, when the thickness of the second layer is reduced and the thickness of the first layer is increased, the thickness of the insulating layer functioning as the channel protective layer is increased without the capacitance of the capacitor being affected. Thus, the thin film transistor substrate according to the present disclosure has improved reliability with more stable properties and allows the capacitor to have a large capacitance.

Furthermore, the thin film transistor substrate according to the present disclosure may further include a first line formed between the substrate and the insulating layer, the first line being arranged along the plane of the substrate together with the gate electrode and the first electrode; and a second line formed above the insulating layer, at a position opposite the first line, and the insulating layer between the first line and the second line may be thicker than the insulating layer above the first electrode.

With this, the insulating layer between the lines can be thick, allowing a reduction in the occurrence of short-circuit between the lines. Thus, the thin film transistor substrate according to the present disclosure has improved reliability.

Furthermore, in the thin film transistor substrate according to the present disclosure, each of the insulating layer on the semiconductor layer and the insulating layer between the first line and the second line may include: a first layer; and a second layer formed on the first layer, and the insulating layer above the first electrode may include only the second layer among the first layer and the second layer.

With this, each of the insulating layer above the gate electrode and the insulating layer between the lines includes the first layer and the second layer, whereas the insulating layer between the electrodes of the capacitor does not include the first layer but includes the second layer. Therefore, when the thickness of the second layer is reduced and the thickness of the first layer is increased, the thickness of the insulating layer functioning as the channel protective layer and the thickness of the insulating layer between the lines are increased without the capacitance of the capacitor being affected. Thus, the thin film transistor substrate according to the present disclosure allows the capacitor to have a large capacitance, as well as has improved reliability by reducing the occurrence of short-circuit between the lines.

Furthermore, in the thin film transistor substrate according to the present disclosure, the gate electrode, the first electrode, and the first line may be formed on the substrate, the gate insulating film may be formed on the gate electrode, the first electrode, and the first line, and the semiconductor layer may be formed on the gate insulating film and above only the gate electrode and the first line among the gate electrode, the first electrode, and the first line.

With this, the gate electrode, the first electrode, and the first line can be formed in the same process, and therefore it is possible to reduce the number of manufacturing processes.

Furthermore, in the thin film transistor substrate according to the present disclosure, the semiconductor layer may be an oxide semiconductor layer.

Furthermore, in the thin film transistor substrate according to the present disclosure, the oxide semiconductor layer may be a transparent amorphous oxide semiconductor.

In this case, since the semiconductor layer is an oxide semiconductor layer, the carrier mobility can be increased.

A method for manufacturing a thin film transistor substrate according to the present disclosure includes: (i) forming a gate electrode and a first electrode of a capacitor above a substrate, the gate electrode and the first electrode being arranged along a plane of the substrate; (ii) forming a gate insulating film, a semiconductor layer, and an insulating layer in sequence by continuously stacking a first insulating film, a semiconductor film, and a second insulating film in sequence, on the gate electrode and the first electrode; and (iii) exposing portions of the semiconductor layer, forming a source electrode and a drain electrode above the insulating layer, and forming a second electrode of the capacitor above the first electrode and the insulating layer, the source electrode and the drain electrode being connected to the semiconductor layer at the exposed portions, and in step (ii), at least a portion of the second insulating film above the first electrode is removed to make the insulating layer above the gate electrode thicker than the insulating layer above the first electrode.

With this, the insulating layer between the first electrode and the second electrode of the capacitor is thinner than the insulating film above the gate electrode, resulting in the capacitor having a large capacitance. The thin film transistor substrate has a channel protective (top-contact) transistor having the source electrode and the drain electrode above the insulating layer. Since the insulating layer formed on the semiconductor layer functions as a channel protective film, the thin film transistor has improved reliability with more stable properties.

Furthermore, since the gate insulating film, the semiconductor layer, and the insulating layer are continuously stacked, the process damage to the semiconductor layer is reduced, allowing a thin film transistor having stable properties to be manufactured. Thus, it is possible to manufacture a reliable thin film transistor substrate which has more stable properties and allows a capacitor to have a large capacitance.

Furthermore, in the method for manufacturing a thin film transistor substrate according to the present disclosure, in step (ii), the gate insulating film originating from the first insulating film may be formed by continuously stacking the first insulating film, the semiconductor film, and the second insulating film in sequence, on the gate electrode and the first electrode, the semiconductor layer may be formed by removing the semiconductor film and the second insulating film above the first electrode, and the insulating layer which includes the second insulating film and a third insulating film may be formed by forming the third insulating film above the gate electrode and the first electrode.

With this, the insulating layer above the gate electrode includes the second insulating film and the third insulating film, whereas the insulating layer between the electrodes of the capacitor does not include the second insulating film but includes the third insulating film. Therefore, when the third insulating layer having a small thickness is formed and the second insulating layer having a large thickness is formed, the thickness of the insulating layer functioning as the channel protective layer is increased without the capacitance of the capacitor being affected. Thus, it is possible to manufacture a reliable thin film transistor substrate which has more stable properties and allows a capacitor to have a large capacitance.

Furthermore, since the common mask can be used in removing the semiconductor film and the second insulating film, it is possible to reduce the number of masks and the number of manufacturing processes.

Furthermore, in the method for manufacturing a thin film transistor substrate according to the present disclosure, step (i) may further include forming a first line above the substrate, the first line being arranged along the plane of the substrate together with the gate electrode and the first electrode, in step (ii), the gate insulating film, the semiconductor layer, and the insulating layer may be formed in sequence by continuously stacking the first insulating film, the semiconductor film, and the second insulating film in sequence, on the gate electrode, the first electrode, and the first line, step (iii) may further include forming a second line above the first line and the insulating layer, and in step (ii), at least a portion of the second insulating film above the first electrode may be removed to make the insulating layer above the gate electrode and the insulating layer between the first line and the second line thicker than the insulating layer above the first electrode.

With this, the insulating layer between the lines can be thick, allowing a reduction in the occurrence of short-circuit between the lines. Thus, it is possible to manufacture a reliable thin film transistor film.

Furthermore, in the method for manufacturing a thin film transistor substrate according to the present disclosure, in step (ii), the gate insulating film originating from the first insulating film may be formed by continuously stacking the first insulating film, the semiconductor film, and the second insulating film in sequence, or the gate electrode, the first electrode, and the first line, the semiconductor layer may be formed by removing the semiconductor film and the second insulating film above the first electrode, and the insulating layer which includes the second insulating film and a third insulating film may be formed by forming the third insulating film above the gate electrode, the first electrode, and the first line.

With this, each of the insulating layer above the gate electrode and the insulating layer between the lines includes the second insulating film and the third insulating film, whereas the insulating layer between the electrodes of the capacitor does not include the second insulating film but includes the third insulating film. Therefore, when the third insulating layer having a small thickness is formed and the second insulating layer having a large thickness is formed, the thickness of the insulating layer functioning as the channel protective layer and the thickness of the insulating layer between the lines are increased without the capacitance of the capacitor being affected. Thus, it is possible to allow the capacitor to have a large capacitance, as well as allow a reduction in the occurrence of short-circuit between the lines, and therefore a reliable thin film transistor substrate can be manufactured.

Furthermore, in the method for manufacturing a thin film transistor substrate according to the present disclosure, the semiconductor layer may be an oxide semiconductor layer.

Furthermore, in the method for manufacturing a thin film transistor substrate according to the present disclosure, the oxide semiconductor layer may be a transparent amorphous oxide semiconductor.

In this case, since the semiconductor layer is an oxide semiconductor layer, a thin film transistor substrate having high carrier mobility can be manufactured.

### Embodiment

Hereinafter, an embodiment of a thin film transistor substrate, a method for manufacturing the same, and an organic EL display device including a thin film transistor substrate will be described with reference to the Drawings. Note that each embodiment described below shows a specific preferred example of the present disclosure. Therefore, the numerical values, shapes, materials, structural elements, arrangement and connection of the structural elements, steps, the processing order of the steps, etc., shown in the following embodiments are mere examples, and are not intended to limit the present disclosure. Consequently, among the structural elements in the following embodiment, elements not recited in any one of the independent claims which indicate the broadest concepts of the present disclosure are described as arbitrary structural elements.

Note that the respective figures are schematic diagrams and are not necessarily precise illustrations. Additionally, components that are essentially the same share the same reference numerals in the respective figures, and overlapping explanations thereof are omitted or simplified.

[Organic EL Display Device]

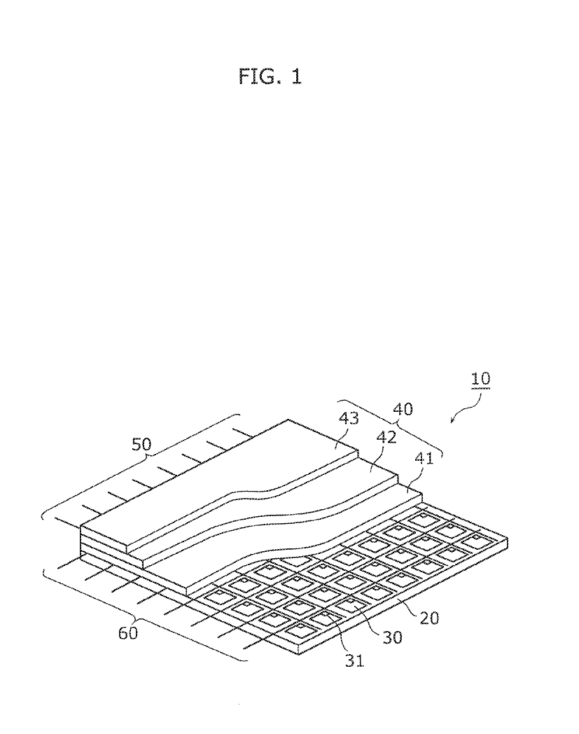

First, the configuration of an organic EL display device 10 according to the present embodiment will be described with reference to FIG. 1. FIG. 1 is a cut-out perspective view of an organic EL display device according to the present embodiment.

As illustrated in FIG. 1, the organic EL display device 10 includes a stacked structure of: a TFT substrate (TFT array substrate) 20 in which plural thin film transistors are disposed; and organic EL elements (light-emitting units) 40 each including an anode 41 which is a lower electrode, an EL layer 42 which is a light-emitting layer including an organic material, and a cathode 43 which is a transparent upper electrode.

A plurality of pixels 30 are arranged in a matrix in the TFT substrate 20, and a pixel circuit 31 is included in each pixel 30.

Each of the organic EL elements 40 is formed corresponding to a different one of the pixels 30, and control of the light emission of the organic EL element 40 is performed according to the pixel circuit 31 provided in the corresponding pixel 30. The organic EL elements 40 are formed on an interlayer insulating film (planarizing film) formed to cover the thin film transistors.

Moreover, the organic EL elements 40 have a configuration in which the EL layer 42 is disposed between the anode 41 and the cathode 43. Furthermore, a hole transport layer is formed stacked between the anode 41 and the EL layer 42, and an electron transport layer is formed stacked between the EL layer 42 and the cathode 43. Note that other organic function layers may be formed between the anode 41 and the cathode 43.

Each pixel 30 is driven by its corresponding pixel circuit 31. Moreover, in the TFT substrate 20, a plurality of gate lines (scanning lines) 50 are disposed along the row direction of the pixels 30, a plurality of source lines (signal lines) 60 are disposed along the column direction of the pixels 30 to cross with the gate lines 50, and a plurality of power supply lines (not illustrated in FIG. 1) are disposed parallel to the source lines 60. The pixels 30 are partitioned from one another by the crossing gate lines 50 and source lines 60, for example.

The gate lines 50 are connected, on a per-row basis, to the gate electrode of the thin film transistors operating as switching elements included in the respective pixel circuits 31. The source lines 60 are connected, on a per-column basis, to the source electrode of the thin film transistors operating as switching elements included in the respective pixel circuits 31. The power supply lines are connected, on a per-column basis, to the drain electrode of the thin film transistors operating as driver elements included in the respective pixel circuits 31.

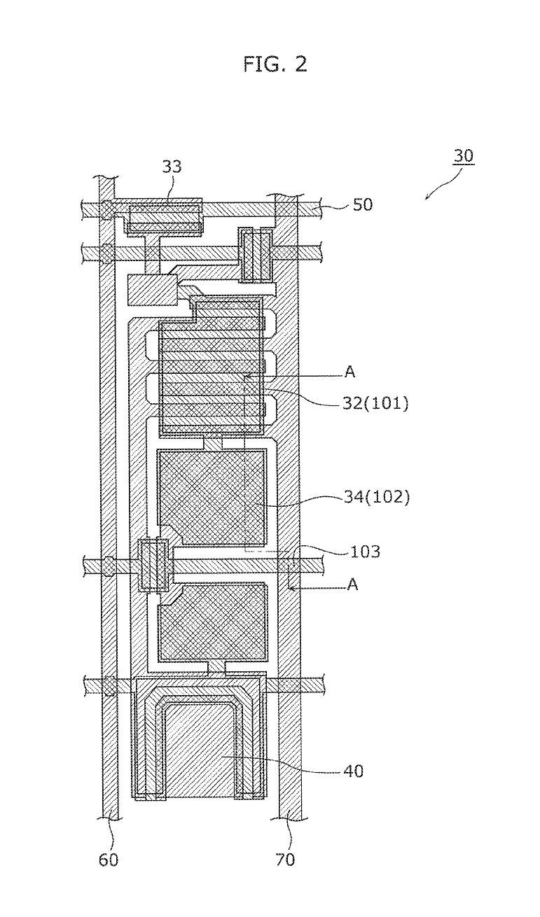

Next, a specific configuration of the pixel 30 will be described with reference to FIG. 2. FIG. 2 is a plan view illustrating the configuration of a pixel in an organic EL display device according to the present embodiment.

As illustrated in FIG. 2, the pixel 30 includes thin film transistors 32 and 33, a capacitor 34, and an organic EL element 40. Furthermore, a gate line 50, a source line 60, and a power supply line 70 which are used for supplying a predetermined voltage to an electrode of each of the thin film transistors are connected to the pixel 30.

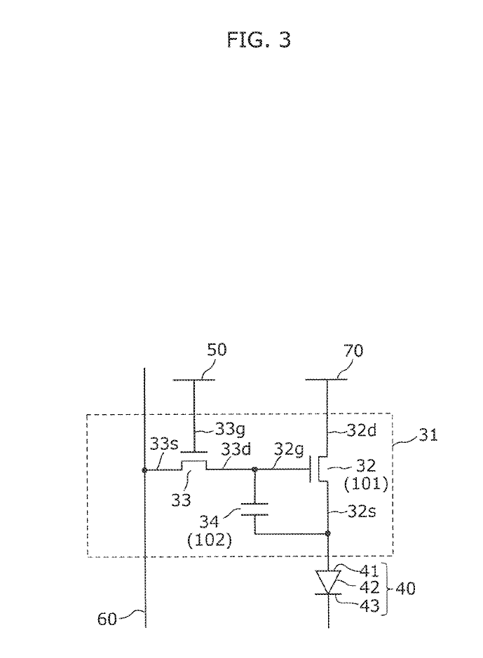

Here, the circuit configuration of the pixel circuit 31 in each pixel 30 will be described with reference to FIG. 3. FIG. 3 is a circuit diagram schematically illustrating the configuration of a pixel circuit in an organic EL display device according to the present embodiment. Note that FIG. 3 illustrates a simplified configuration of the pixel 30 illustrated in FIG. 2.

As illustrated in FIG. 3, the pixel circuit 31 includes a thin film transistor 32 that operates as a driver element, a thin film transistor 33 that operates as a switching element, and a capacitor 34 that stores data to be displayed by the corresponding pixel 30. In the present embodiment, the thin film transistor 32 is a driver transistor for driving the organic EL elements 40, and the thin film transistor 33 is a switching transistor for selecting the pixel 30.

The thin film transistor 32 includes: a gate electrode 32g connected to a drain electrode 33d of the thin film transistor 33 and one end of the capacitor 34; a drain electrode 32d connected to the power supply line 70; a source electrode 32s connected to the anode 41 of the organic EL element 40 and the other end of the capacitor 34; and a semiconductor film (not illustrated in the Drawings). The thin film transistor 32 supplies current corresponding to data voltage held in the capacitor 34 from the power supply line 70 to the anode 41 of the organic EL elements 40 via the source electrode 32s. With this, in the organic EL elements 40, drive current flows from the anode 41 to the cathode 43 whereby the EL layer 42 emits light.

The thin film transistor 33 includes: a gate electrode 33g connected to the gate line 50; a source electrode 33s connected to the source line 60; a drain electrode 33d connected to one end of the capacitor 34 and the gate electrode 32g of the thin film transistor 32; and a semiconductor film (not illustrated in the Drawings). When a predetermined voltage is applied to the gate line 50 and the source line 60 connected to the thin film transistor 33, the voltage applied to the source line 60 is held as data voltage in the capacitor 34.

Note that the organic EL display device 10 having the above-described configuration uses the active-matrix system in which display control is performed for each pixel 30 located at the cross-point between the gate line 50 and the source line 60. With this, the thin film transistors 32 and 33 of each pixel 30 (of each of subpixels R, G, and B) cause the corresponding organic EL element 40 to selectively emit light, whereby a desired image is displayed.

[Thin Film Transistor Substrate]

Hereinafter, the thin film transistor substrate according to the present embodiment will be described. Note that the thin film transistor substrate according to the present embodiment has a bottom-gate and channel protective (top-contact) thin film transistor.

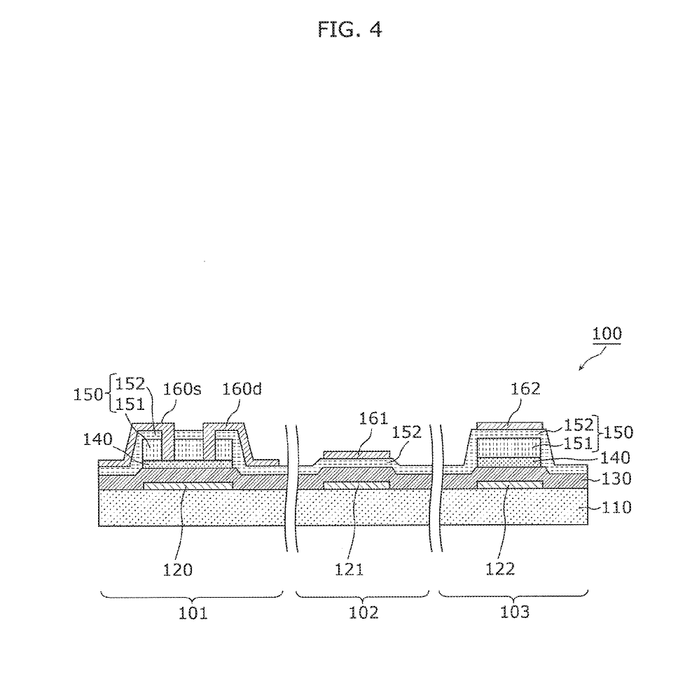

FIG. 4 is a schematic diagram of a cross section of a thin film transistor substrate according to the present embodiment

As illustrated in FIG. 4, a thin film transistor substrate 100 according to the present embodiment includes a thin film transistor 101, a capacitor 102, and a line cross-over section 103. The thin film transistor 101, the capacitor 102, and the line cross-over section 103 are arranged on a substrate 110 along a plane thereof. In other words, the thin film transistor 101, the capacitor 102, and the line cross-over section 103 are formed in mutually different flat regions on the substrate 110. Stated differently, when the substrate 110 is seen in plan view, the thin film transistor 101, the capacitor 102, and the line cross-over section 103 are formed in mutually different regions.

Note that the cross section of the thin film transistor substrate 100 illustrated in FIG. 4 corresponds to the A-A cross section of FIG. 2, for example. The thin film transistor 101 corresponds to the thin film transistor 32 illustrated in FIG. 3, for example. The capacitor 102 corresponds to the capacitor 34 illustrated in FIG. 3, for example. The line cross-over section 103 is where the respective lines overlap.

As illustrated in FIG. 4, the thin film transistor substrate 100 includes the substrate 110, a gate electrode 120, a first electrode 121, a first line 122, a gate insulating film 130, a semiconductor layer 140, an insulating layer 150, a source electrode 160s, a drain electrode 160d, a second electrode 161, and a second line 162. The insulating layer 150 includes a first layer 151 and a second layer 152.

The thin film transistor 101 includes the substrate 110, the gate electrode 120, the gate insulating film 130, the semiconductor layer 140, the insulating layer 150 (the first layer 151 and the second layer 152), the source electrode 160s, and the drain electrode 160d. The capacitor 102 includes the substrate 110, the first electrode 121, the gate insulating film 130, the insulating layer 150 (the second layer 152), and the second electrode 161. The line cross-over section 103 includes the substrate 110, the first line 122, the gate insulating film 130, the semiconductor layer 140, the insulating layer 150 (the first layer 151 and the second layer 152), and the second line 162.

The substrate 110 is a substrate configured from an electrically insulating material. For example, the substrate 110 is a substrate configured from a glass material, such as alkali-free glass, quartz glass, or high-heat resistant glass; a resin material such as polyethylene, polypropylene, or polyimide; a semiconductor material such as silicon or gallium arsenide; or a metal material such as stainless steel coated with an insulating layer.

Note that the substrate 110 may be a flexible substrate such as a resin substrate. In this case, the thin film transistor substrate 100 can be used as a flexible display.

The gate electrode 120 is formed in a predetermined shape, on the substrate 110. The gate electrode 120 is an electrode configured from a conductive material. For example, for the material of the gate electrode 120, it is possible to use a metal such as molybdenum, aluminum, copper, tungsten, titanium, manganese, chromium, tantalum, niobium, silver, gold, platinum, palladium, indium, nickel, neodymium, etc.; a metal alloy; a conductive metal oxide such as indium tin oxide (ITO), aluminum doped zinc oxide (AZO), gallium doped zinc oxide (GZO), etc.; or a conductive polymer such as polythiophene, polyacetylene, etc. Furthermore, the gate electrode 120 may have a multi-layered structure obtained by stacking these materials. As one example, the gate electrode 120 is an alloy of molybdenum and tungsten and has a thickness of 75 nm.

The first electrode 121 is formed in a predetermined shape, on the substrate 110. The material and thickness of the first electrode 121 can be, for example, the same as the material and thickness of the gate electrode 120.

The first line 122 is formed in a predetermined shape, on the substrate 110. The material and thickness of the first line 122 can be, for example, the same as the material and thickness of the gate electrode 120.

Note that the gate electrode 120, the first electrode 121, and the first line 122 may be configured from the same material. This allows the gate electrode 120, the first electrode 121, and the first line 122 to be formed in the same process, and thus the number of masks that are used in patterning and the number of manufacturing processes can be reduced.

The gate electrode 120, the first electrode 121, and the first line 122 are formed on the substrate 110 such as to be arranged along a plane of the substrate 110 (in the direction parallel to the principal surface of the substrate 110). This means that the gate electrode 120, the first electrode 121, and the first line 122 are formed in the same layer. For example, the gate electrode 120, the first electrode 121, and the first line 122 are formed in mutually different flat regions on the substrate 110.

The gate insulating film 130 is formed on the gate electrode 120. For example, the gate insulating film 130 is formed on the gate electrode 120 and the substrate 110 so as to cover the gate electrode 120. Specifically, the gate insulating film 130 is formed above the substrate 110 so as to expand over the entire surface thereof and cover the gate electrode 120, the first electrode 121, and the first line 122.

The gate insulating film 130 is configured from an electrically insulating material. For example, the gate insulating film 130 is a single-layered film, such as a silicon oxide film, a silicon nitride film, a silicon oxynitride film, an aluminum oxide film, a tantalum oxide film, or a hafnium oxide film, or a stacked film thereof. As one example, the gate insulating film 130 has a stacked structure of a silicon oxide film and a silicon nitride film which are 85 nm and 65 nm, respectively, in thickness.

The semiconductor layer 140 is formed in a predetermined shape, on the gate insulating film 130. The semiconductor layer 140 is a channel layer of the thin film transistor 101. For example, the semiconductor layer 140 is formed above only the gate electrode 120 and the first line 122 among the gate electrode 120, the first electrode 121, and the first line 122. In other words, the semiconductor layer 140 is not formed above the first electrode 121.

Specifically, the semiconductor layer 140 is formed on the gate insulating film 130, at a position opposite the gate electrode 120 and at a position opposite the first line 122. For example, the semiconductor layer 140 is formed in the shape of an island on the gate insulating film 130 above the gate electrode 120 and the first line 122.

The semiconductor layer 140 is, for example, an oxide semiconductor layer. An oxide semiconductor material containing at least one from among indium (In), gallium (Ga), and zinc (Zn) is used for the material of the semiconductor layer 140. For example, the semiconductor layer 140 is configured from a transparent amorphous oxide semiconductor (TAOS) such as amorphous indium gallium zinc oxide (InGaZnO: IGZO). As one example, the thickness of the semiconductor layer 140 is 30 nm.

The In:Ga:Zn ratio is, for example, approximately 1:1:1. Furthermore, although the In:Ga:Zn ratio may be in a range of 0.8 to 1.2:0.8 to 1.2:0.8 to 1.2, the ratio is not limited to this range.

A thin film transistor having a channel layer configured from a transparent amorphous oxide semiconductor has high carrier mobility, and is suitable for a large screen and high-definition display device. Furthermore, since a transparent amorphous oxide semiconductor allows low-temperature film-forming, a transparent amorphous oxide semiconductor can be easily formed on a flexible substrate of plastic or film, etc.

The insulating layer 150 is formed on the semiconductor layer 140 and above the first electrode 121 and the first line 122 so as to expose portions of the semiconductor layer 140. The insulating layer 150 on the semiconductor layer 140 functions as a channel protective layer which protects the semiconductor layer 140. The insulating layer 150 above the first electrode 121 defines capacitance of the capacitor 102. The insulating layer 150 between the first line 122 and the second line 162 is an insulating layer for preventing short-circuit between the lines in the line cross-over section 103.

The insulating layer 150 includes the first layer 151 and the second layer 152 formed on the first layer 151. Specifically, the insulating layer 150 above the gate electrode 120, that is, the insulating layer 150 on the semiconductor layer 140, includes the first layer 151 and the second layer 152. The insulating layer 150 above the first electrode 121 includes only the second layer 152 among the first layer 151 and the second layer 152. The insulating layer 150 between the first line 122 and the second line 162 includes the first layer 151 and the second layer 152.

The first layer 151 is formed above the gate electrode 120 and the first line 122. Specifically, the first layer 151 is formed on the semiconductor layer 140. For example, the first layer 151 is formed above the gate electrode 120, at a position opposite the gate electrode 120, and is formed above the first line 122, at a position opposite the first line 122.

This means that the first layer 151 is formed above only the gate electrode 120 and the first line 122 among the gate electrode 120, the first electrode 121, and the first line 122. In other words, the first layer 151 is not formed above the first electrode 121. That is, the first layer 151 is formed on the semiconductor layer 140 only.

The first layer 151 is configured from an electrically insulating material. For example, the first layer 151 is a film configured from an inorganic material, such as a silicon oxide film, a silicon nitride film, a silicon oxynitride film, or an aluminum oxide film, or a single-layered film such as a film configured from an inorganic material containing silicon, oxygen, and carbon, or a stacked film thereof. As one example, the first layer 151 is a silicon oxide film and has a thickness of 120 nm.

The second layer 152 is formed on the first layer 151. Specifically, the second layer 152 is formed on the first layer 151 and the gate insulating film 130 so as to cover the first layer 151.

The second layer 152 is configured from an electrically insulating material. For example, the second layer 152 is a film configured from an inorganic material, such as a silicon oxide film, a silicon nitride film, a silicon oxynitride film, or an aluminum oxide film, or a single-layered film such as a film configured from an inorganic material containing silicon, oxygen, and carbon, or a stacked film thereof. As one example, the second layer 152 is a silicon oxide film and has a thickness of 120 nm.

Furthermore, portions of the insulating layer 150 (the first layer 151 and the second layer 152) have openings that pass through the insulating layer 150. Specifically, contact holes for exposing portions of the semiconductor layer 140 are formed in the first layer 151 and the second layer 152. The semiconductor layer 140 is connected to the source electrode 160s and the drain electrode 160d via the opening portions (the contact holes).

Thus, the thin film transistor 101 and the line cross-over section 103 each include the first layer 151 and the second layer 152. In contrast, the capacitor 102 includes only the second layer 152 among the first layer 151 and the second layer 152. In other words, the capacitor 102 does not include the first layer 151.

Therefore, the capacitance of the capacitor 102 depends on the thickness of the second layer 152 and does not depend on the thickness of the first layer 151. Accordingly, it is possible to give the capacitor 102 a large capacitance by reducing the thickness of the second layer 152.

Meanwhile, since the thin film transistor 101 includes the first layer 151 and the second layer 152, it is possible to allow the insulating layer 150 to remain thick as the channel protective layer by increasing the thickness of the first layer 151. Accordingly, the thickness of the channel protective layer can be increased without the capacitance of the capacitor 102 being affected, which allows the thin film transistor 101 to have improved reliability with more stable properties.

Furthermore, since the line cross-over section 103 includes the first layer 151 and the second layer 152, the distance between the first line 122 and the second line 162 is a total of the thickness of the first layer 151 and the thickness of the second layer 152. In the line cross-over section 103, in order to prevent short-circuit between the first line 122 and the second line 162, it is preferable that the distance between the lines be set to a large value.

In the present embodiment, it is possible to increase the distance between the first line 122 and the second line 162 without the capacitance of the capacitor 102 being affected, by increasing the thickness of the first layer 151. Therefore, the possibility of short-circuit between the first line 122 and the second line 162 can be reduced.

The source electrode 160s and the drain electrode 160d are formed in a predetermined shape, above the insulating layer 150. In other words, the source electrode 160s and the drain electrode 160d are formed above the insulating layer 150, so as to be connected to the semiconductor layer 140 at the exposed portions of the semiconductor layer 140. Specifically, the source electrode 160s and the drain electrode 160d are connected to the semiconductor layer 140 via the contact holes formed in the insulating layer 150, and are arranged opposing each other on the insulating layer 150, by being separated in the horizontal direction along the substrate.

The source electrode 160s and the drain electrode 160d are electrodes configured from a conductive material. For example, a material that is the same as the material of the gate electrode 120 may be used for the source electrode 160s and the drain electrode 160d. As one example, the source electrode 160s and the drain electrode 160d are molybdenum films and have a thickness of 100 nm.

The second electrode 161 is formed in a predetermined shape, above the insulating layer 150. In other words, the second electrode 161 is formed above the insulating layer 150, at a position opposite the first electrode 121. Specifically, the second electrode 161 is formed on the second layer 152, at a position opposite the first electrode 121. The material and thickness of the second electrode 161 can be, for example, the same as the material and thickness of the gate electrode 120.

The second line 162 is formed in a predetermined shape, above the insulating layer 150. In other words, the second electrode 162 is formed above the insulating layer 150, at a position opposite the first electrode 122. Specifically, the second line 162 is formed on the second layer 152, at a position opposite the first line 122. The material and thickness of the second line 162 can be, for example, the same as the material and thickness of the gate electrode 120.

Note that all the source electrode 160s, the drain electrode 160d, the second electrode 161, and the second line 162 may be configured from the same material. This allows the source electrode 160s, the drain electrode 160d, the second electrode 161, and the second line 162 to be formed in the same process, and thus the number of masks that are used in patterning and the number of manufacturing processes can be reduced.

[Method for Manufacturing Thin Film Transistor Substrate]

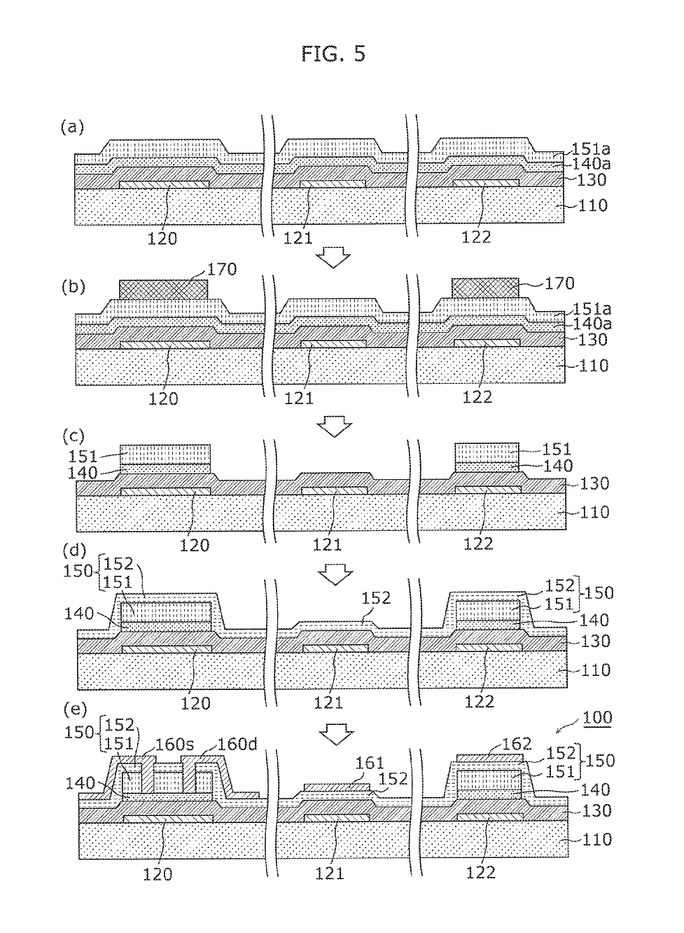

Next, a method for manufacturing a thin film transistor substrate according to the present embodiment will be described with reference to FIG. 5. FIG. 5 is a schematic diagram of a cross section of a thin film transistor substrate according to the present embodiment illustrating a manufacturing method.

First, as illustrated in (a) of FIG. 5, the substrate 110 is prepared, and the gate electrode 120, the first electrode 121, and the first line 122 of a predetermined shape are formed above the substrate 110 so as to be arranged along a plane of the substrate 110. For example, a metal film is formed on the substrate 110 using a sputtering method, and the metal film is processed using a photolithography method and a wet etching method to form the gate electrode 120, the first electrode 121, and the first line 122 of the predetermined shape. Note that wet etching of the metal film can be performed using a mixed chemical solution of a hydrogen peroxide solution (H₂O₂) and organic acid, for example.

Next, the gate insulating film 130, the semiconductor layer 140, and the insulating layer 150 are formed in sequence by continuously stacking a first insulating film, a semiconductor film, and a second insulating film in sequence, on the gate electrode 120, the first electrode 121, and the first line 122. Note that as illustrated in (a) of FIG. 5, the first insulating film is the gate insulating film 130, the semiconductor film is a semiconductor film 140a, and the second insulating film is an insulating film 151a, for example.

Continuous film forming herein means that films are continuously stacked in such a manner as to exclude from therebetween all other processes represented by a washing process and an inspection process. Specifically, first, the substrate 110 above which the gate electrode 120, the first electrode 121, and the first line 122 have been formed is placed inside a chamber of a film-forming device. Thereafter, the pressure inside the chamber is sufficiently reduced so that the substrate 110 can be kept in a clean state without touching the air.

In a sufficient depressurized state (a vacuum state), the gate insulating film 130 is initially formed on the gate electrode 120, the first electrode 121, and the first line 122. For example, the gate insulating film 130 is formed by forming a silicon nitride film and a silicon oxide film in sequence using a plasma chemical vapor deposition (CVD) method on the gate electrode 120, the first electrode 121, the first line 122, and the substrate 110 so as to cover the gate electrode 120, the first electrode 121, and the first line 122.

The silicon nitride film can be formed, for example, using silane gas (SiH₄), ammonium gas (NH₃), and nitrogen gas (N₂) as introduced gases. For example, the silicon nitride film is formed using ammonium gas (NH₃) at a temperature of 400° C. The silicon oxide film can be formed, for example, using silane gas (SiH₄) and nitrogen monoxide gas (N₂O) as introduced gases.

Next, the semiconductor film 140a is formed on the gate insulating film 130 using a sputtering method, for example. Specifically, an amorphous InGaZnO film is formed on the gate insulating film 130 using a sputtering method in the oxygen atmosphere using a target material having an In:Ga:Zn composition ratio of 1:1:1

Subsequently, the insulating film 151a is formed on the semiconductor film 140a using a plasma CVD method, for example. Specifically, the silicon oxide film is formed on the semiconductor film 140a using silane gas (SiH₄) at a temperature of 300° C.

In this way, the gate insulating film 130, the semiconductor film 140a, and the insulating film 151a are continuously stacked in sequence; the gate insulating film 130 is formed first. The continuous film forming makes it possible to form layers while maximally keeping away pollutant impurity elements floating in the air and without contacting a chemical solution such as a resist solution and a wet etching solution.

Note that in the present embodiment, it may be possible to form the semiconductor film 140a and the insulating film 151a in sequence without contact to the air using a multi-chamber film-forming device including a plurality of chambers. It may also be possible to form the gate insulating film 130, the semiconductor film 140a, and the insulating film 151a in sequence without contact to the air using a multi-chamber film-forming device including a plurality of chambers.

Next, a resist 170 of a predetermined shape is formed on the insulating film 151a as illustrated in (b) of FIG. 5. Specifically, the resist 170 is formed using a photolithography method above only the gate electrode 120 and the first line 122 among the gate electrode 120, the first electrode 121, and the first line 122. In other words, the resist 170 is not formed above the first electrode 121.

Next, the semiconductor layer 140 and the first layer 151 are formed by patterning the semiconductor film 140a and the insulating film 151a as illustrated in (c) of FIG. 5. For example, the insulating film 151a is removed using a dry etching method except for the area where the resist 170 has been formed. Furthermore, the semiconductor film 140a is removed using a wet etching method except for the area where the resist 170 has been formed.

Specifically, when the insulating film 151a is a silicon oxide film, a reactive ion etching (RIE) method can be used as the dry etching method. At this time, for example, carbon tetrafluoride (CF₄) and oxygen gas (O₂) can be used as etching gases. Parameters such as gas flow rate, pressure, applied power, frequency, etc. are set as appropriate depending on the substrate size, the thickness of the film to be etched, etc.

When the semiconductor film 140a is InGaZnO, the wet etching can be performed using a mixed chemical solution of, for example, phosphoric acid (H₃PO₄), nitric acid (HNO₃), acetic acid (CH₃COOH), and water. Thus, the semiconductor film 140a and the insulating film 151a above the first electrode 121 are removed to form the semiconductor layer 140 and the first layer 151. The semiconductor layer 140 is the semiconductor film 140a patterned in a predetermined shape and is formed above the gate electrode 120 and the first line 122. The first layer 151 is the second insulating film 151a patterned in a predetermined shape and is formed above the gate electrode 120 and the first line 122.

Next, a third insulating film is formed above the gate electrode 120, the first electrode 121, and the first line 122, to form the insulating layer 150 which includes the second insulating film and the third insulating film. Specifically, the second layer 152 is formed on the first layer 151 and the gate insulating film 130 as illustrated in (d) of FIG. 5. For example, a silicon oxide film is formed on the first layer 151 and the gate insulating film 130 using a plasma CVD method. For example, the silicon oxide film is formed using silane gas (SiH₄) at a temperature of 300° C. After the second layer 152 is formed, heat treatment (an annealing process) is performed at 350° C. for one hour.

Thus, the insulating layer 150 includes the second insulating film (the first layer 151) and the third insulating film (the second layer 152) above the gate electrode 120 and the first line 122, and does not include the second insulating film (the first layer 151) but includes the third insulating film (the second layer 152) above the first electrode 121. This means that the insulating layer 150 includes insulating films formed in the same process. For example, the insulating layer 150 includes the third insulating film (the second layer 152) formed so as to expand over the entire surface thereof and the second insulating layer (the first layer 151) patterned in a predetermined shape.

Next, as illustrated in (e) of FIG. 5, the insulating layer 150 (the first layer 151 and the second layer 152) is patterned in a predetermined shape so as to expose portions of the semiconductor layer 140. Specifically, contact holes are formed in the insulating layer 150 so that portions of the semiconductor layer 140 of the thin film transistor 101 are exposed. For example, portions of the insulating layer 150 of the thin film transistor 101 are removed by etching, so as to form contact holes.

Specifically, first, portions of the insulating layer 150 are etched using a photolithography method and a dry etching method to form contact holes on regions of the semiconductor layer 140 that become a source-contact region and a drain-contact region. For example, when the first layer 151 and the second layer 152 are silicon oxide films, the RIE method can be used as the dry etching method. At this time, for example, carbon tetrafluoride (CF₄) and oxygen gas (O₂) can be used as etching gases. Parameters such as gas flow rate, pressure, applied power, frequency, etc. are set as appropriate depending on the substrate size, the thickness of the film to be etched, etc.

Next, the source electrode 160s and the drain electrode 160d which are to be connected to the semiconductor layer 140 are formed above the insulating layer 150. For example, the source electrode 160s and the drain electrode 160d are formed in a predetermined shape above the insulating layer 150 so as to fill in the contact holes formed in the insulating layer 150. Furthermore, the second electrode 161 and the second line 162 are formed in a predetermined shape above the insulating layer 150.

Specifically, the source electrode 160s and the drain electrode 160d are spaced apart from each other and formed above the insulating layer 150 and inside the contact holes. Furthermore, the second electrode 161 is formed above the insulating layer 150 and the first electrode 121, and the second line 162 is formed above the insulating layer 150 and the first line 122.

More specifically, a molybdenum film is formed above the insulating layer 150 and inside the contact holes using a sputtering method, and the molybdenum film is patterned using a photolithography method and a wet etching method, to form the source electrode 160s, the drain electrode 160d, the second electrode 161, and the second line 162. Note that wet etching of the molybdenum film can be performed using a mixed chemical solution of a hydrogen peroxide solution (H₂O₂) and organic acid, for example.

Lastly, although not illustrated in the Drawings, a passivation film (planarizing film) is formed so as to cover the source electrode 160s, the drain electrode 160d, the second electrode 161, and the second line 162. For example, the passivation film is a silicon oxide film and has a thickness of 460 nm. Specifically, a silicon oxide film is formed as the passivation film using silane gas (SiH₄) at a temperature of 300° C. by a plasma CVD method. Thereafter, heat treatment (an annealing process) is performed at 300° C. for one hour.

This is how the thin film transistor substrate 100 can be manufactured.

### Comparative Example

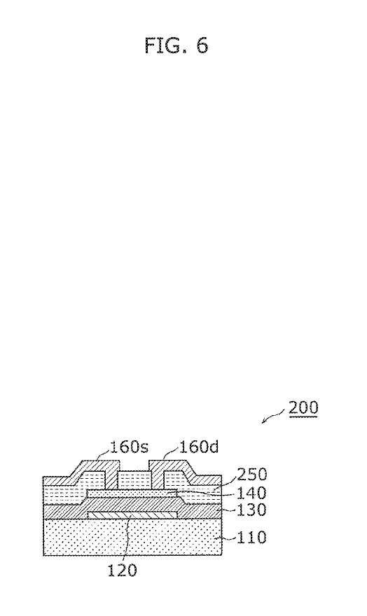

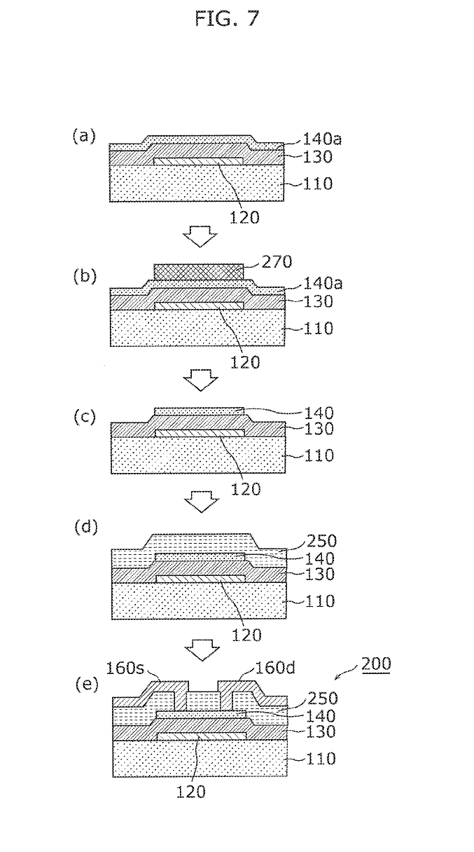

Next, a thin film transistor according to a comparative example will be described with reference to FIG. 6 and FIG. 7. The thin film transistor according to the comparative example is a comparison target for showing an advantageous effect of the thin film transistor substrate 100 according to the present embodiment.

FIG. 6 is a schematic diagram of a cross section of a thin film transistor according to the comparative example.

As illustrated in FIG. 6, a thin film transistor 200 according to the comparative example includes the substrate 110, the gate electrode 120, the gate insulating film 130, the semiconductor layer 140, an insulating layer 250, the source electrode 160s, and the drain electrode 160d. Note that there are instances where overlapping explanations of components that are essentially the same as those included in the thin film transistor substrate 100 are omitted.

The insulating layer 250 is formed on the semiconductor layer 140. For example, the insulating layer 250 is formed on the semiconductor layer 140 and the gate insulating film 130 so as to cover the semiconductor layer 140.

Portions of the insulating layer 250 have openings that pass through the insulating layer 250. Specifically, contact holes for exposing portions of the semiconductor layer 140 are formed in the insulating layer 250. The semiconductor layer 140 is connected to the source electrode 160s and the drain electrode 160d via the opening portions (the contact holes).

The insulating layer 250 is configured from an electrically insulating material. For example, the insulating layer 250 is a film configured from an inorganic material, such as a silicon oxide film, a silicon nitride film, a silicon oxynitride film, or an aluminum oxide film, or a single-layered film such as a film configured from an inorganic material containing silicon, oxygen, and carbon, or a stacked film thereof. As one example, the insulating layer 250 is a silicon oxide film and has a thickness of 240 nm.

Next, a method for manufacturing the thin film transistor 200 according to the comparative example will be described with reference to FIG. 7. FIG. 7 is a schematic diagram of a cross section of a thin film transistor according to the comparative example illustrating a manufacturing method.

Formation of the gate electrode 120 and continuous formation of the gate insulating film 130 and the semiconductor film 140a illustrated in (a) of FIG. 7 are the same as the formation of the gate electrode 120 and the continuous formation of the gate insulating film 130 and the semiconductor film 140a illustrated in (a) of FIG. 5, and therefore explanations thereof are omitted.

As illustrated in (b) of FIG. 7, a resist 270 of a predetermined shape is formed on the semiconductor film 140a. Specifically, the resist 270 is formed using a photolithography method above the gate electrode 120, at a position opposite the gate electrode 120.

Next, the semiconductor layer 140 is formed by patterning the semiconductor film 140a as illustrated in (c) of FIG. 7. For example, the semiconductor film 140a is removed using a wet etching method except for the area where the resist 270 has been formed. When the semiconductor film 140a is InGaZnO, the wet etching can be performed using a mixed chemical solution of, for example, phosphoric acid (H₃PO₄), nitric acid (HNO₃), acetic acid (CH₃COOH), and water.

Next, the insulating layer 250 is formed on the semiconductor layer 140 and the gate insulating film 130 as illustrated in (d) of FIG. 7. For example, a silicon oxide film is formed on the semiconductor layer 140 and the gate insulating film 130 using a plasma CVD method so as to cover the semiconductor layer 140.

Next, as illustrated in (e) of FIG. 7, the insulating layer 250 is patterned in a predetermined shape so as to expose portions of the semiconductor layer 140. Specifically, contact holes are formed in the insulating layer 250 so that portions of the semiconductor layer 140 are exposed. For example, portions of the insulating layer of the thin film transistor 101 are removed by etching, so as to form contact holes. The etching removal method is as described above.

This is how the thin film transistor 200 according to the comparative example can be manufactured.

The thin film transistor 200 according to the comparative example differs from the thin film transistor 101 according to the present embodiment in that the semiconductor layer 140 and the insulating layer 250 are not continuously stacked. Specifically, the semiconductor layer 140 of the thin film transistor 200 according to the comparative example is exposed to the resist 270.

[PBTS Test]

Next, the results of a positive bias temperature stress (PBTS) test performed on the thin film transistor 200 according to the comparative example and the thin film transistor 101 according to the present embodiment will be described.

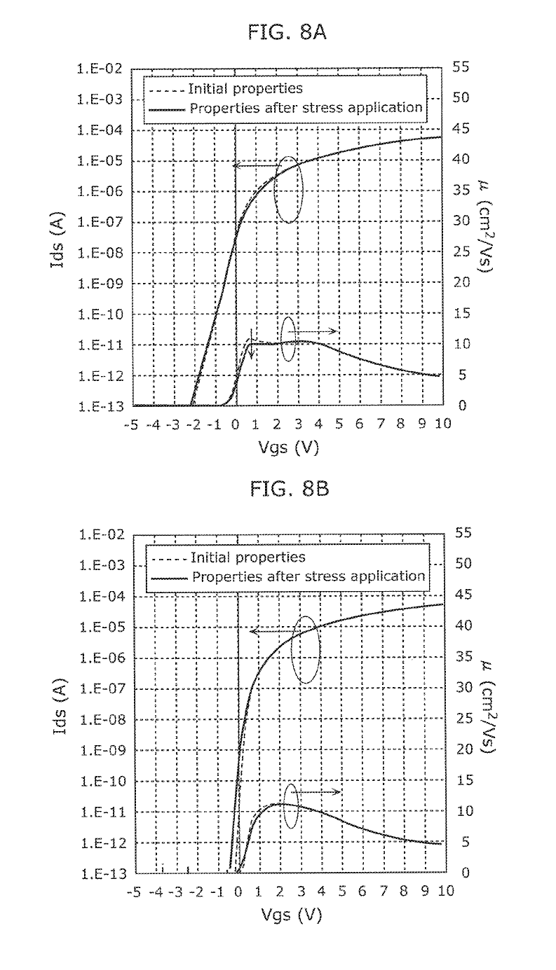

FIG. 8A illustrates the relationship between gate voltage and each of current and mobility measured in a PBTS test for a thin film transistor according to the comparative example. FIG. 8B illustrates the relationship between gate voltage and each of current and mobility measured in a PBTS test for a thin film transistor according to the present embodiment.

The PBTS test is performed on the thin film transistor 200 and the thin film transistor 101 under the following conditions: gate-source voltage V_{gs}=+20 V, drain-source voltage V_{ds}=0 V, temperature T=90° C., and time t=2,000 sec.

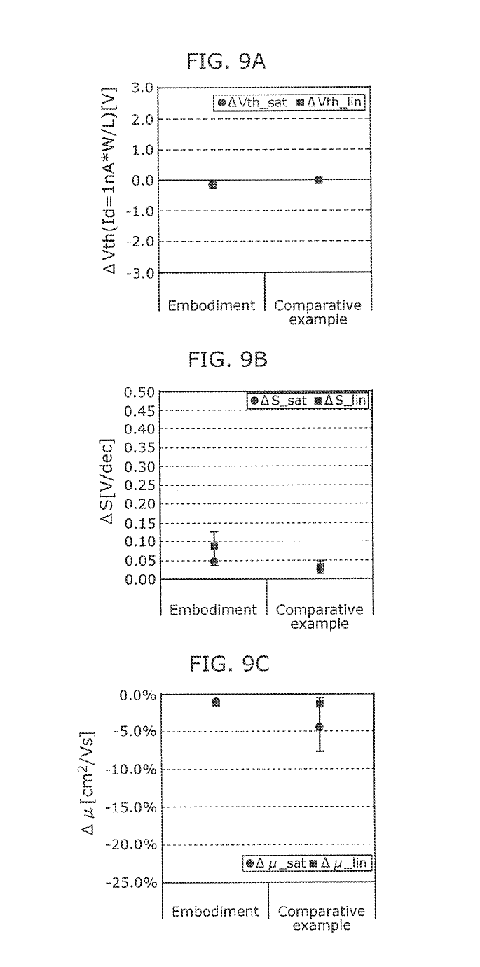

FIG. 9A illustrates changes in threshold voltage measured in a PBTS test for thin film transistors according to the present embodiment and the comparative example. In FIG. 9A, a circle represents the amount of change ΔVth_sat in threshold voltage in a saturated zone, and a square represents the amount of change ΔVth_lin in threshold voltage in a linear zone.

As illustrated in FIG. 9A, no major changes are observed in threshold voltage Vₜₕ after stress application in both the thin film transistor 200 according to the comparative example and the thin film transistor 101 according to the present embodiment. Note that this is considered to be the effect of plasma treatment using ammonia gas (NH₃) when the gate insulating film 130 is formed.

FIG. 9B illustrates changes in S value measured in a PBTS test for thin film transistors according to the present embodiment and the comparative example. In FIG. 9B, a circle represents the amount of change ΔS_sat in S value in a saturated zone, and a square represents the amount of change ΔS_lin in S value in a linear zone.

The S value is a subthreshold swing value which is one of values indicating properties of a thin film transistor. Drain current I_{ds} changes more rapidly with respect to the gate-source voltage V_{gs} as the S value decreases.

As illustrated in FIG. 9B, the amount of change in S value of the thin film transistor 101 according to the present embodiment is greater than the amount of change in S value of the thin film transistor 200 according to the comparative example after stress application. This means that as a result of stress application, the S value of the thin film transistor 101 varies more than that of the thin film transistor 200. Therefore, the thin film transistor 101 is considered to have less stable properties than the thin film transistor 200 according to the comparative example.

However, a comparison between FIG. 8A and FIG. 8B, for example, shows that the slope of drain current I_{ds} is greater in the thin film transistor 101 according to the present embodiment than in the thin film transistor 200 according to the comparative example. Therefore, the thin film transistor 101 has better transfer properties than the thin film transistor 200 according to the comparative example.

FIG. 9C illustrates changes in mobility measured in a PBTS test for thin film transistors according to the present embodiment and the comparative example. In FIG. 9C, a circle represents the amount of change Δμ_sat in mobility μ in a saturated zone, and a square represents the amount of change Δμ_lin in mobility μ in a linear zone.

As illustrated in FIG. 9C, the amount of change in mobility of the thin film transistor 101 according to the present embodiment is less than the amount of change in mobility of the thin film transistor 200 according to the comparative example after stress application. This means that even after long-term use of the thin film transistor 101, changes in the mobility of the thin film transistor 101 are not large.

In particular, the mobility variations in the saturated zone are small as illustrated in FIG. 9C. This means that a mobility peak (hereinafter, referred to as a mobility curve peak) does not appear for the thin film transistor 101 according to the present embodiment.

For example, as illustrated in FIG. 8A, for the thin film transistor 200 according to the comparative example, a mobility curve peak appears around the gate-source voltage V_{gs}=0.6 V in initial properties (before stress application). Consequently, the mobility is significantly reduced after stress application as illustrated in FIG. 8A.

In contrast, for the thin film transistor 101 according to the present embodiment, a mobility curve peak does not appear in initial properties as illustrated in FIG. 8B. Therefore, the mobility is not significantly reduced after stress application as illustrated in FIG. 8B, meaning that the thin film transistor 101 has stable properties.

As described above, the PBTS test shows that for the thin film transistor 101 according to the present embodiment, the changes in threshold voltage are reduced, and the changes in mobility are also reduced, even after stress application. In particular, the mobility curve peak is suppressed, and the significant reduction of the mobility, which is observed for the thin film transistor 200 according to the comparative example, is suppressed. Thus, the thin film transistor 101 according to the present embodiment has high reliability with more stable properties.

[NBTS Test]

Next, the results of a negative bias temperature stress (NBTS) test performed on the thin film transistor 200 according to the comparative example and the thin film transistor 101 according to the present embodiment will be described.

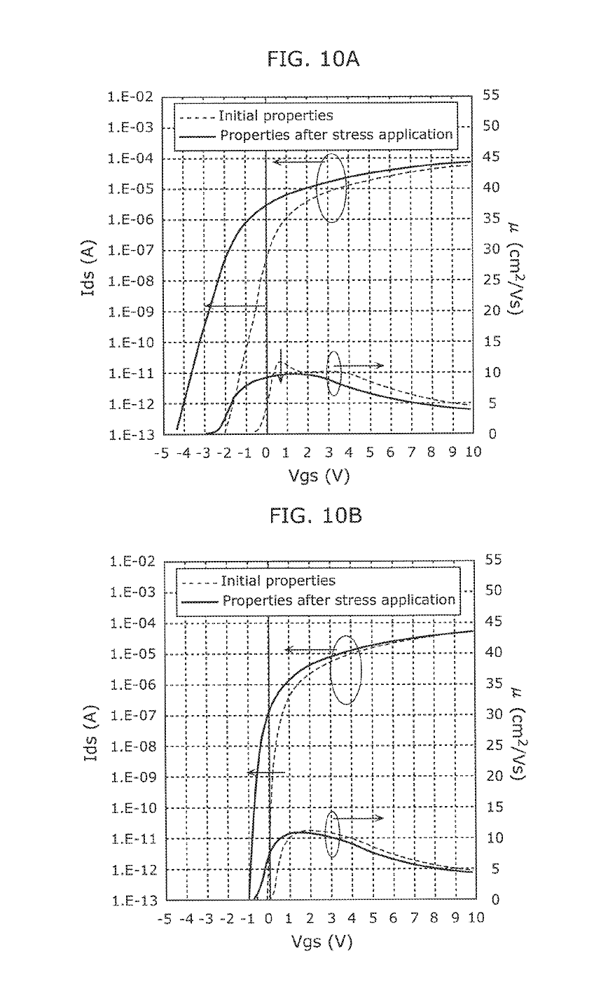

FIG. 10A illustrates the relationship between gate voltage and each of current and mobility measured in an NBTS test for a thin film transistor according to the comparative example. FIG. 10B illustrates the relationship between gate voltage and each of current and mobility measured in an NBTS test for a thin film transistor according to the present embodiment.

The NBTS test is performed on the thin film transistor 200 and the thin film transistor 101 under the following conditions' gate-source voltage V_{gs}=−20 V, drain-source voltage V_{ds}=0 V, temperature T=90° C., and time t=2,000 sec.

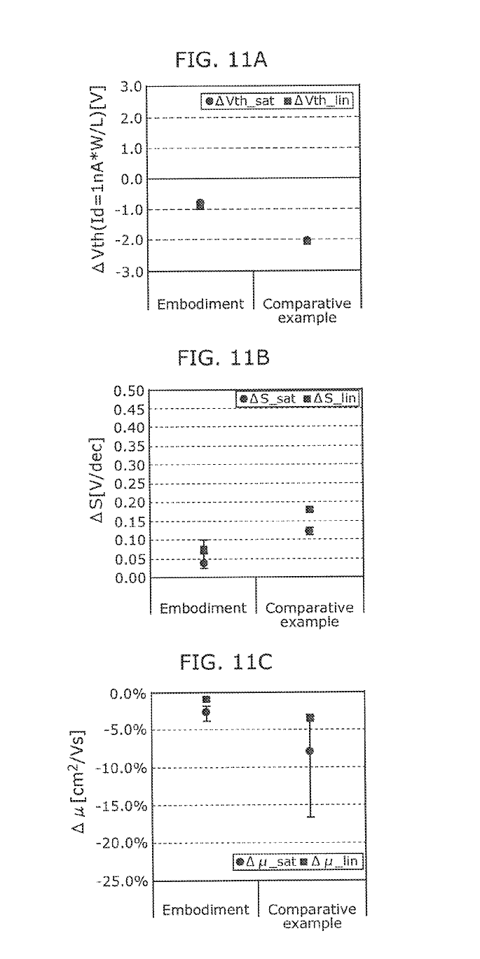

FIG. 11A illustrates changes in threshold voltage measured in an NBTS test for thin film transistors according to the present embodiment and the comparative example. In FIG. 11A, a circle represents the amount of change ΔVth_sat in threshold voltage in a saturated zone, and a square represents the amount of change ΔVth_lin in threshold voltage in a linear zone.

As illustrated in FIG. 11A, the amount of change in threshold voltage Vₜₕ of the thin film transistor 101 according to the present embodiment is less than the amount of change in threshold voltage Vₜₕ of the thin film transistor 200 according to the comparative example after stress application. This means that even after long-term use of the thin film transistor 101, variations in the threshold voltage of the thin film transistor 101 are not large.

FIG. 11B illustrates changes in S value measured in an NBTS test for thin film transistors according to the present embodiment and the comparative example. In FIG. 11B, a circle represents the amount of change ΔS_sat in S value in a saturated zone, and a square represents the amount of change ΔS_lin in S value in a linear zone.

As illustrated in FIG. 11B, both in the saturated zone and in the linear zone, the amount of change in S value of the thin film transistor 101 according to the present embodiment is less than the amount of change in S value of the thin film transistor 200 according to the comparative example after stress application. This means that even after long-term use of the thin film transistor 101, changes in the S value of the thin film transistor 101 are not large.

FIG. 11C illustrates changes in mobility measured in an NBTS test for thin film transistors according to the present embodiment and the comparative example. In FIG. 11C, a circle represents the amount of change Δμ_sat in mobility μ in a saturated zone, and a square represents the amount of change Δμ_lin in mobility μ in a linear zone.

As illustrated in FIG. 11C, the amount of change in mobility of the thin film transistor 101 according to the present embodiment is less than the amount of change in mobility of the thin film transistor 200 according to the comparative example after stress application.

In particular, the mobility variations in the saturated zone are small as illustrated in FIG. 11C. That is, for the thin film transistor 101 according to the present embodiment, a mobility curve peak does not appear as illustrated in FIG. 10B. Note that as illustrated in FIG. 10A, when a mobility curve peak appears, the mobility of the thin film transistor 200 according to the comparative example is reduced by about 2.63%. For the thin film transistor 101 according to the present embodiment, a mobility curve peak does not appear, resulting in a reduction in the mobility being small; thus, the thin film transistor 101 has high reliability with stable properties.

[Advantageous Effects, Etc.]

As described above, the thin film transistor substrate 100 according to the present embodiment includes: the substrate 110; the gate electrode 120 and the first electrode 121 of the capacitor 102 formed above the substrate 110, the gate electrode 120 and the first electrode 121 being arranged along a plane of the substrate 110; the gate insulating film 130 formed on the gate electrode 120; the semiconductor layer 140 formed on the gate insulating film 130; the insulating layer 150 formed on the semiconductor layer 140 and above the first electrode 121, the insulating layer 150 leaving portions of the semiconductor layer 140 exposed; the source electrode 160s and the drain electrode 160d formed above the insulating layer 150, the source electrode 160s and the drain electrode 160d being connected to the semiconductor layer 140 at the exposed portions of the semiconductor layer 140; and the second electrode 161 of the capacitor formed above the insulating layer 150, at a position opposite the first electrode 121, wherein the insulating layer 150 above the gate electrode 120 is thicker than the insulating layer 150 above the first electrode 121.

Specifically, the thin film transistor substrate 100 according to the present embodiment is a channel protective (top-contact) transistor having the source electrode 160s and the drain electrode 160d above the insulating layer 150. Therefore, since a channel protective film on the semiconductor layer 140 is thick, the thin film transistor 101 has improved reliability with more stable properties.

Furthermore, in the thin film transistor substrate 100 according to the present embodiment, each of the insulating layer 150 on the semiconductor layer 140 of the thin film transistor 101, and the insulating layer 150 between the first line 122 and the second line 162 of the line cross-over section 103 includes the first layer 151 and the second layer 152. In contrast, the insulating layer 150 between the first electrode 121 and the second electrode 161 of the capacitor 102 does not include the first layer 151 but includes the second layer 152.

Therefore, since the first layer 151 is not formed between the first electrode 121 and the second electrode 161, the capacitance of the capacitor 102 does not depend on the thickness of the first layer 151. It is possible to give the capacitor 102 a large capacitance by reducing the thickness of the second layer 152. Meanwhile, the first layer 151 having an increased thickness is capable of sufficiently functioning to protect the channel of the thin film transistor 101 and reducing the occurrence of short-circuit between the lines of the line cross-over section 103.

In this way, it is possible to provide a function of protecting the channel and reduce the occurrence of short-circuit between the lines, without reducing the capacitance, by increasing the thickness of the first layer 151, and, furthermore, it is possible to increase the capacitance by reducing the thickness of the second layer 152.

Furthermore, in the method for manufacturing the thin film transistor substrate 100 according to the present embodiment, the gate insulating film 130, the semiconductor layer 140, and the insulating layer 150 are continuously stacked. Accordingly, the process damage to the semiconductor layer 140 is reduced, resulting in reduced amounts of changes in the minus threshold shift amount, the S value, and the mobility as described with reference to FIG. 8A to FIG. 11B. With this, the thin film transistor 101 included in the thin film transistor substrate 100 has improved reliability with more stable properties.

That is, the thin film transistor substrate 100 according to the present embodiment allows a capacitor to have a large capacitance, and has improved reliability with more stable properties.

### Other Embodiments

As described above, the embodiment is described as an exemplification of the technique disclosed in the present application. However, the technique according to the present disclosure is not limited to the foregoing embodiment, and can also be applied to embodiments to which a change, substitution, addition, or omission is executed as necessary.

For example, a configuration in which the thin film transistor 101, the capacitor 102, and the line cross-over section 103 are provided on the substrate 110 is described in the above embodiment, but this is not the only example. Specifically, a thin film transistor substrate according to the present disclosure is not required to include the line cross-over section so long as it includes the thin film transistor and the capacitor. In other words, the thin film transistor substrate is not required to include the first line and the second line.

Furthermore, a configuration in which the insulating layer 150 includes the first layer 151 and the second layer 152 is described in the above embodiment, but this is not the only example. The insulating layer according to the present disclosure may include three or more layers. For example, the first layer according to the present disclosure may include plural layers, and the second layer according to the present disclosure may include plural layers. Alternatively, each of the first layer and the second layer may include plural layers.

Furthermore, the insulating layer according to the present disclosure may be a single layer. In other words, it is sufficient that the insulating layer is formed on the semiconductor layer and above the first electrode so as to expose portions of the semiconductor layer, in addition to which the insulating layer above the gate electrode is thicker than the insulating layer above the first electrode.

For example, in FIG. 4, the first layer 151 may be formed above the first electrode 121. In this case, a portion of the first layer 151 above the first electrode 121 is removed by etching or the like, so as to make the first layer 151 above the gate electrode 120 thicker than the first layer 151 above the first electrode 121.

In addition, the semiconductor layer 140 may have been formed above the first electrode 121 in this case. Specifically, the semiconductor layer 140 and the first layer 151 may be formed above the first electrode 121 and the gate insulating film 130. For example, it is sufficient that only a portion of the insulating film 151a above the first electrode 121 is etched after the gate insulating film 130, the semiconductor film 140a, and the insulating film 151a are continuously stacked as illustrated in FIG. 5.

Furthermore, the gate insulating film 130 is not required to be formed on the first electrode 121 and the first line 122.

Furthermore, an insulating layer or the like may be formed between the substrate 110 and each of the gate electrode 120, the first electrode 121, and the first line 122. In other words, it is sufficient that the gate electrode 120, the first electrode 121, and the first line 122 are formed above the substrate 110.

Furthermore, in the above embodiment, the oxide semiconductor to be used in the semiconductor layer is not limited to amorphous InGaZnO. For example, a polycrystalline semiconductor such as polycrystalline InGaO or a monocrystalline semiconductor such as silicon may be used.

Furthermore, in the above embodiment, an organic EL display device is described as a display device which includes a thin film transistor substrate, but the thin film transistor substrate in the above embodiment can be applied to other display devices, such as a liquid-crystal device, which include active-matrix substrates.

Furthermore, display devices (display panels) such as the above-described organic EL display device can be used as a flat panel display, and can be applied to various electronic devices having a display panel, such as television sets, personal computers, mobile phones, and so on. In particular, display devices (display panels) such as the above-described organic EL display device are suitable for large screen and high-definition display devices.

Moreover, embodiments obtained through various modifications to each embodiment and variation which may be conceived by a person skilled in the art as well as embodiments realized by arbitrarily combining the structural elements and functions of the embodiment and variation without materially departing from the spirit of the present disclosure are included in the present disclosure.

### INDUSTRIAL APPLICABILITY

The thin film transistor substrate and the method for manufacturing the same according to the present disclosure can be used, for example, in display devices such as organic EL display devices.

### REFERENCE SIGNS LIST

10 organic EL display device
20 TFT substrate
30 pixel
31 pixel circuit
32, 33, 101, 200 thin film transistor
32d, 33d, 160d drain electrode
32g, 33g, 120 gate electrode
32s, 33s, 160s source electrode
34 capacitor
40 organic EL element
41 anode
42 EL layer
43 cathode
50 gate line
60 source line
70 power supply line
100 thin film transistor substrate
102 capacitor
103 line cross-over section
110 substrate
121 first electrode
122 first line
130 gate insulating film
140 semiconductor layer
140a semiconductor film
150, 250 insulating layer
151 first layer
151a insulating film
152 second layer
161 second electrode
162 second line
170, 270 resist

1. A thin film transistor substrate comprising:
a substrate;
a gate electrode and a first electrode of a capacitor formed above the substrate, the gate electrode and the first electrode being arranged along a plane of the substrate;
a gate insulating film formed on the gate electrode;
a semiconductor layer formed on the gate insulating film;
an insulating layer formed on the semiconductor layer and above the first electrode, the insulating layer leaving portions of the semiconductor layer exposed;
a source electrode and a drain electrode formed above the insulating layer, the source electrode and the drain electrode being connected to the semiconductor layer at the exposed portions of the semiconductor layer; and
a second electrode of the capacitor formed above the insulating layer, at a position opposite the first electrode,
wherein the insulating layer above the gate electrode is thicker than the insulating layer above the first electrode.

2. The thin film transistor substrate according to claim 1,
wherein the insulating layer above the gate electrode includes:
a first layer; and
a second layer formed on the first layer, and
the insulating layer above the first electrode includes only the second layer among the first layer and the second layer.

3. The thin film transistor substrate according to claim 1, further comprising:
a first line formed between the substrate and the insulating layer, the first line being arranged along the plane of the substrate together with the gate electrode and the first electrode; and
a second line formed above the insulating layer, at a position opposite the first line,
wherein the insulating layer between the first line and the second line is thicker than the insulating layer above the first electrode.

4. The thin film transistor substrate according to claim 3,
wherein each of the insulating layer on the semiconductor layer and the insulating layer between the first line and the second line includes:
a first layer; and
a second layer formed on the first layer, and
the insulating layer above the first electrode includes only the second layer among the first layer and the second layer.

5. The thin film transistor substrate according to claim 3,
wherein the gate electrode, the first electrode, and the first line are formed on the substrate,
the gate insulating film is formed on the gate electrode, the first electrode, and the first line, and
the semiconductor layer is formed on the gate insulating film and above only the gate electrode and the first line among the gate electrode, the first electrode, and the first line.

6. The thin film transistor substrate according to claim 1,
wherein the semiconductor layer is an oxide semiconductor layer.

7. The thin film transistor substrate according to claim 6,
wherein the oxide semiconductor layer is a transparent amorphous oxide semiconductor.

8. A method for manufacturing a thin film transistor substrate, the method comprising:
(i) forming a gate electrode and a first electrode of a capacitor above a substrate, the gate electrode and the first electrode being arranged along a plane of the substrate;
(ii) forming a gate insulating film, a semiconductor layer, and an insulating layer in sequence by continuously stacking a first insulating film, a semiconductor film, and a second insulating film in sequence, on the gate electrode and the first electrode; and
(iii) exposing portions of the semiconductor layer, forming a source electrode and a drain electrode above the insulating layer, and forming a second electrode of the capacitor above the first electrode and the insulating layer, the source electrode and the drain electrode being connected to the semiconductor layer at the exposed portions,
wherein in step (ii), at least a portion of the second insulating film above the first electrode is removed to make the insulating layer above the gate electrode thicker than the insulating layer above the first electrode.

9. The method for manufacturing a thin film transistor substrate according to claim 8,
wherein in step (ii),
the gate insulating film originating from the first insulating film is formed by continuously stacking the first insulating film, the semiconductor film, and the second insulating film in sequence, on the gate electrode and the first electrode,
the semiconductor layer is formed by removing the semiconductor film and the second insulating film above the first electrode, and
the insulating layer which includes the second insulating film and a third insulating film is formed by forming the third insulating film above the gate electrode and the first electrode.

10. The method for manufacturing a thin film transistor substrate according to claim 8,
wherein step (i) further includes forming a first line above the substrate, the first line being arranged along the plane of the substrate together with the gate electrode and the first electrode,
in step (ii), the gate insulating film, the semiconductor layer, and the insulating layer are formed in sequence by continuously stacking the first insulating film, the semiconductor film, and the second insulating film in sequence, on the gate electrode, the first electrode, and the first line,
step (iii) further includes forming a second line above the first line and the insulating layer, and
in step (ii), at least a portion of the second insulating film above the first electrode is removed to make the insulating layer above the gate electrode and the insulating layer between the first line and the second line thicker than the insulating layer above the first electrode.

11. The method for manufacturing a thin film transistor substrate according to claim 10,
wherein in step (ii),
the gate insulating film originating from the first insulating film is formed by continuously stacking the first insulating film, the semiconductor film, and the second insulating film in sequence, on the gate electrode, the first electrode, and the first line,
the semiconductor layer is formed by removing the semiconductor film and the second insulating film above the first electrode, and
the insulating layer which includes the second insulating film and a third insulating film is formed by forming the third insulating film above the gate electrode, the first electrode, and the first line.

12. The method for manufacturing a thin film transistor substrate according to claim 8,
wherein the semiconductor layer is an oxide semiconductor layer.

13. The method for manufacturing a thin film transistor substrate according to claim 12,
wherein the oxide semiconductor layer is a transparent amorphous oxide semiconductor.
